(19) United States
(12) Patent Application Publication
(10) Pub. No.: US 2009/0194434 A1
(43) Pub. Date: Aug. 6, 2009

(54) Unit dose packaging system with reusable electronics component

(76) Inventors: Kevin Ellis, Cary, NC (US); Mike Weston, Chapel Hill, NC (US); Rune K. Haraldsson, Garner, NC (US); Christopher J. Hession, Knightdale, NC (US); William J. Knouse, Raleigh, NC (US); Caleb Loftin, Raleigh, NC (US)

Correspondence Address: MEADWESTVACO CORPORATION;ATTN: IP LEGAL DEPARTMENT, 1021 MAIN CAMPUS DRIVE, RALEIGH, NC, 27606, US

(21) Appl. No.: 12/025,439

(22) Filed: Feb. 4, 2008

(51) Int. Cl. B65D 83/04; H05K 7/14; B65D 25/02; B65D 25/34; B65D 55/02; G06K 19/06; B65D 5/38

(52) U.S. Cl. 206/1.5; 206/531; 220/694; 220/737; 235/493; 206/531; 206/534; 53/410; 206/1.5; 229/125.125; 600/300; 361/600

(57) ABSTRACT

Described herein is an apparatus and method for attaching a removable and reusable electronic component to a to a slide card that can be preprinted with electrical traces for the purpose of collecting data on pill expression. A removable and reusable electronic component can be coupled with a slide card incorporating preprinted electrical traces, using a hub like plastic seating component attached to and through the slide card.

### BACKGROUND

Unit dose packaging is an attractive packaging format for certain pharmaceutical applications because it is convenient, yet sturdy enough to be opened and closed numerous times until the course of medication is completed, and also enables the user to track the consumption of doses according to the prescribed schedule. Examples of such packaging are described in U.S. Pat. No. 6,047,829 (Johnstone), which is commonly assigned with this application.

The Johnstone patent relates to a unit dose paperboard package that includes an outer paperboard sleeve, an inner paperboard slide card that is lockably retained within the sleeve. The sleeve includes a plurality of side panels operatively connected to each other such that one of said plurality of side panels includes a first inner slide card releasing means, and another of said side panels includes a second inner slide card releasing means, such that the inner slide card retaining and releasing means are located substantially adjacent to said unit dose dispensing means.

An improvement over that described and claimed in U.S. Pat. No. 6,047,829 is contained in another commonly assigned patent (U.S. Pat. No. 6,412,636). In this patent the package is rendered less susceptible to unintentional opening and has improved structural stability. Child resistance is a feature particularly desired for pharmaceutical packaging, and is mandated by the Poison Prevention Packaging Act of 1970.

In addition to child resistance it is also desirable that the unit dose packaging system be senior friendly to permit easy withdrawal of the package contents with minimum manipulation. Such a withdrawal means should be easy to use even if the patients manual dexterity or strength is reduced.

The aforesaid patents permit the user to track consumption of medication doses (e.g., pills) by visually inspecting the packaging. However, significantly more data can be obtained pertaining to the consumption of unit doses if a reusable electronics component that automatically tracked and transmitted dosing events was able to be removably integrated with the packaging.

### SUMMARY

One embodiment of the disclosure describes a unit dose paperboard package insert. The unit dose package insert includes a paperboard blank comprised of a bottom panel and a top panel. The bottom panel includes one or more areas of weakness outlined by perforations. The bottom panel further includes an electrical trace element having at least first and second ends positioned away from the areas of weakness wherein the electrical trace element intersects the one or more areas of weakness such that when an area of weakness is compromised the electrical trace element is broken for that area of weakness. The top panel includes one or more unit dose cut out areas and an electronics seating hub component cut out area. The unit dose package insert also includes a blister pack comprised of one or more sealed unit doses positionable atop the bottom panel such that the unit doses are substantially above the unit dose cut out areas. There is also an electronics seating hub component adapted to mechanically receive a removable, reusable electronics component wherein the electronics seating hub component is positioned proximate to the termination of the electrical trace element ends. The top panel substantially covers and is adhered to the bottom panel to secure the blister packs and electronics seating hub component securely between the top and bottom panel such that the sealed unit doses protrude through the unit dose cut out areas and the electronics seating hub component protrudes through the electronics seating hub component cut out area.

The blank can further include a crease that defines a boundary between the top panel and the bottom panel such that folding the blank along the crease positions the top panel substantially covering the bottom panel aligning the cut out areas of the top panel with the areas of weakness of the bottom panel. A pair of additional creases can also be included in which the space in between the creases defines an end panel when the unit dose package insert is folded back over itself along each crease.

In one embodiment, the electronics seating hub component comprises a housing including first and second pairs of opposing walls. One wall of the first pair of opposing walls includes at least one opening at the base of the wall that is adapted to receive a tab that is attached to an electronics component. The opposite wall of the first pair of opposing walls includes a cut out area to facilitate insertion and removal of the electronics component within the electronics seating hub component. One wall of the second pair of opposing walls includes a detent adapted to receive a corresponding inverted detent that is attached to an electronics component such that the electronics component remains seated in place upon lining up the detent and inverted detent.

In another embodiment, the electronics seating hub component comprises a pair of opposed rigid side members, each including a dovetail slot extending substantially the length of each side member. There is also rigid cross member including one or more electrical contacts that are electrically coupled with the electrical trace element ends. An electronics component having a corresponding dovetail slot can be slidably seated with the electronics seating hub component.

In another embodiment, the disclosure describes a reusable electronics component that can be electrically coupled with a disposable unit dose package to collect and disseminate data pertaining to the expression of unit doses. The reusable electronics component includes a seating mechanism adapted to fit into an electronics seating hub component, a microcontroller, an RF module coupled with the microcontroller for sending and receiving data wirelessly, an electrical trace contact interface coupled with the microcontroller for electrically coupling the reusable electronics component with electrical traces present on the disposable unit dose package, and a software application coupled with the microcontroller for detecting when a unit dose has been expelled from the disposable unit dose package. The reusable electronics component can further include a display for displaying data, an indicator light for providing a visual status indication, a speaker for providing an audible status indication, a power jack for recharging an internal power source of the electronics component, and a data port for providing a wired data output mechanism.

In yet another embodiment of the disclosure, a method of assembling a unit dose package insert is described. A blank comprised of a top panel and a bottom panel, wherein the top panel and a bottom panel include one or more creases, cut outs, and perforations required to accommodate a blister pack and an electronics seating hub component is formed. Electrical traces are applied to the blank in a desired pattern so as to ensure each unit dose has a portion of the electrical trace associated therewith. The blister pack is adhered to the bottom panel of the blank such that each unit dose is substantially over a perforated area. The electronics seating hub component is also adhered to the bottom panel such that electrical trace terminations are coupled with corresponding electrical trace contacts in the electronics seating hub component. The top panel is then sealed to the bottom panel thereby encasing the blister pack and the electronics seating hub component firmly and immovably between the top and bottom panels of the unit dose package insert. The electrical traces can be comprised of conductive ink that is printed onto the blank.

In another embodiment of the disclosure, a unit dose package system is described. The unit dose package system includes a slide card insert comprised of a blank that includes a bottom panel and a top panel. The bottom panel includes one or more areas of weakness outlined by perforations. The bottom panel further includes an electrical trace element having at least first and second ends positioned away from the areas of weakness wherein the electrical trace element intersects the one or more areas of weakness such that when an area of weakness is compromised the electrical trace element is broken for that area of weakness. The top panel includes one or more unit dose cut out areas and an electronics seating hub component cut out area. The unit dose package insert also includes a blister pack comprised of one or more sealed unit doses positionable atop the bottom panel such that the unit doses are substantially above the unit dose cut out areas. There is also an electronics seating hub component adapted to mechanically receive a removable, reusable electronics component wherein the electronics seating hub component is positioned proximate to the termination of the electrical trace element ends. The top panel substantially covers and is adhered to the bottom panel to secure the blister packs and electronics seating hub component securely between the top and bottom panel such that the sealed unit doses protrude through the unit dose cut out areas and the electronics seating hub component protrudes through the electronics seating hub component cut out area. The unit dose package system further includes a reusable electronics component mechanically and electrically coupled with the electronics seating hub component to create a complete electrical circuit between each unit dose and the reusable electronics component. A cover adapted to receive the slide card insert such that the slide card insert is lockably and slidably engaged within the cover is also included.

### BRIEF DESCRIPTION OF THE DRAWINGS

FIG. 1 illustrates a unit dose packaging system according to one embodiment of the disclosure including an internal slide card and outer sleeve with child resistant button release means.

FIGS. 2a and 2b illustrate views of the slide card.

FIG. 3 is an illustration of an electronics component that can be removably coupled with a slide card according to one embodiment of the disclosure.

FIG. 4 is a block diagram illustrating components of an electronic component like that illustrated in FIG. 3.

FIG. 5 illustrates one embodiment of an electronics seating hub and an electronics component.

FIG. 6 illustrates another embodiment of an electronics seating hub and an electronics component.

FIG. 7 is an exploded view of the various layers and components that comprise a finished slide card according to an embodiment of the disclosure.

FIG. 8 is a data flow diagram that describes a process for assembling a slide card according to an embodiment of the disclosure.

### DETAILED DESCRIPTION OF THE EMBODIMENTS

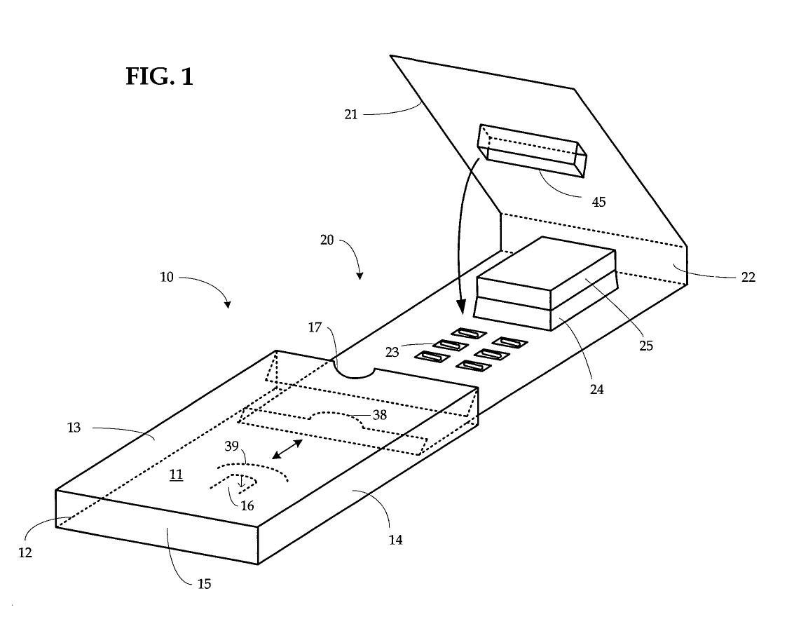

Referring to FIG. 1, an embodiment of the unit dose package comprises a slide card 20, which can be releasably, lockably engaged with an outer sleeve 10. The outer sleeve 10 is comprised of a top panel 11 and a bottom panel 12, which are foldably connected by side panels 13 and 14, and an end panel 15, which secures one end opening of the package.

The top panel 11 can include a release mechanism 16, which is formed by a series of connected cuts in the sleeve substrate made by conventional techniques. The cut edges form a flexible tab that can be depressed to exert pressure on one or more layers of substrate underlying top panel 11 to release a locking mechanism 38 of slide card 20 that engages a reciprocal locking mechanism 39 of the outer sleeve 10 and allow the slide card 20 to be withdrawn sufficiently to expose one or more blisters 23 that have been associated with slide card 20.

Top panel 11 can further include a notch 17 that provides a finger hold to facilitate withdrawal of slide card 20. A corresponding notch (not shown) having similar dimensions as notch 17 is positioned parallel to but offset from notch 17 in the edge of the bottom panel. Notch 17 is shown positioned close to the center of the edge of top panel 11 while its corresponding notch on the opposite side panel is positioned off center such that there is incomplete overlap with notch 17. The position of these notches along the outer edges of the sleeve 10 and their placement in relation to each other may be varied depending on the overall dimensions of the package.

Slide card 20 can be folded along creases to form an end panel 22 and also define a second area 21 that can be utilized for additional blister packaging. An electronics component 25 is shown seated within an electronics seating hub component 24. The electronics component 25 when seated in electronics seating hub component 24 have a height dimension that is very close to the height of end panel 22. This is so that when the slide card 20 is fully inserted in outer sleeve 10, the end panel 22 cannot be collapsed. This provides an additional measure of child resistance to the packaging. In addition, a protruding element 45 is placed such that when the slide card 20 is folded over onto itself to create opposing top and bottom panels, the protruding element 45 on the top panel will be proximate to the electronics component 25/electronics seating hub component 24 on the bottom panel in a manner that prevents the top panel from sliding out further enhancing the child resistant aspect of the packaging.

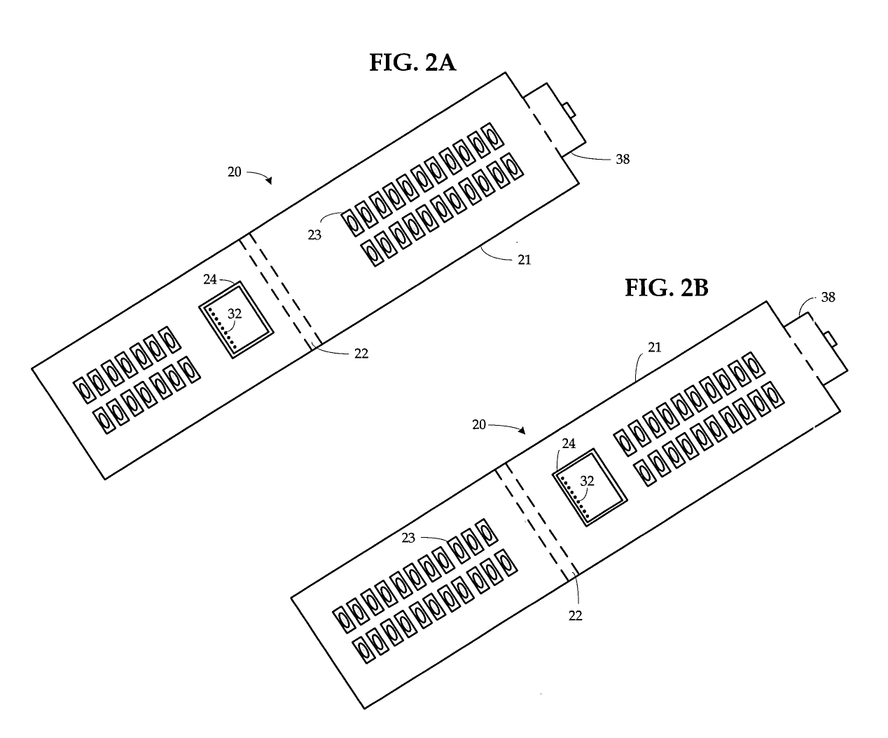

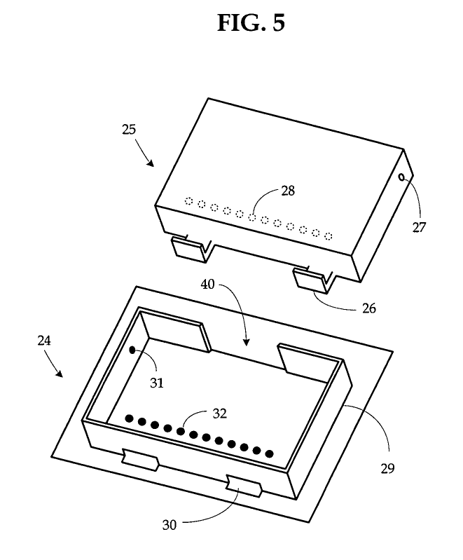

Referring to FIGS. 2A and 2B, a slide card 20 is shown in an isometric view. As just described, the slide card 20 includes an electronics seating hub component 24 that can be positioned proximate to one or more electrical trace ends (not shown) so as to enable the contacts 28 (see, e.g., FIG. 5) of the electronics component 25 to operatively connect or to the one or more electrical trace ends. Dashed lines define creases for an end panel 22 and a locking mechanism 38. The slide card 20 can be folded along the creases to create the end panel 22 and a locking mechanisms 38 such that when the slide card 20 is folded and inserted into the outer sleeve 10, a packaging solution is created that allows the slide card 20 to be coupled with the outer sleeve 10 in a slidable and lockable manner. It is noted that the protruding element is not shown in FIGS. 2A and 2B, but can of course be present.

When folded, the slide card 20 forms two opposed panels each capable of containing blister packs 23. In FIG. 2A, the electronics seating hub component 24 is shown on what could be considered the lower panel of the slide card 20 while in FIG. 2B, the electronics seating hub component 24 is shown on what could be considered the upper panel of the slide card 20. Thus, the electronics seating hub component 24 can be situated strategically on the slide card 20 and is not necessarily restricted to a single location.

Also shown within the electronics seating hub component 24 is a set of electrical trace contacts 32. These contacts terminate a corresponding set of electrical traces (not shown) that can be pre-printed on the slide card to correspond with each unit dose of the blister packs 23. When an electronics component 25 is operatively seated within the electronics seating hub component 24, a corresponding set of contacts 28 (see, FIG. 5 for an example embodiment) operatively engages the trace contacts to complete an electronics circuit. It should be noted that the placement and number of electrical trace contacts 32 within an electronics seating hub component 24 can be a design choice that is best adapted to a given configuration.

In practical use of a packaging system, a user can simply remove and re-use an electrical component 25 each time a new slide card 20 of unit doses is received. As an additional benefit, the height dimension of the electrical component 25 adds additional structural support to a folded slide card when seated.

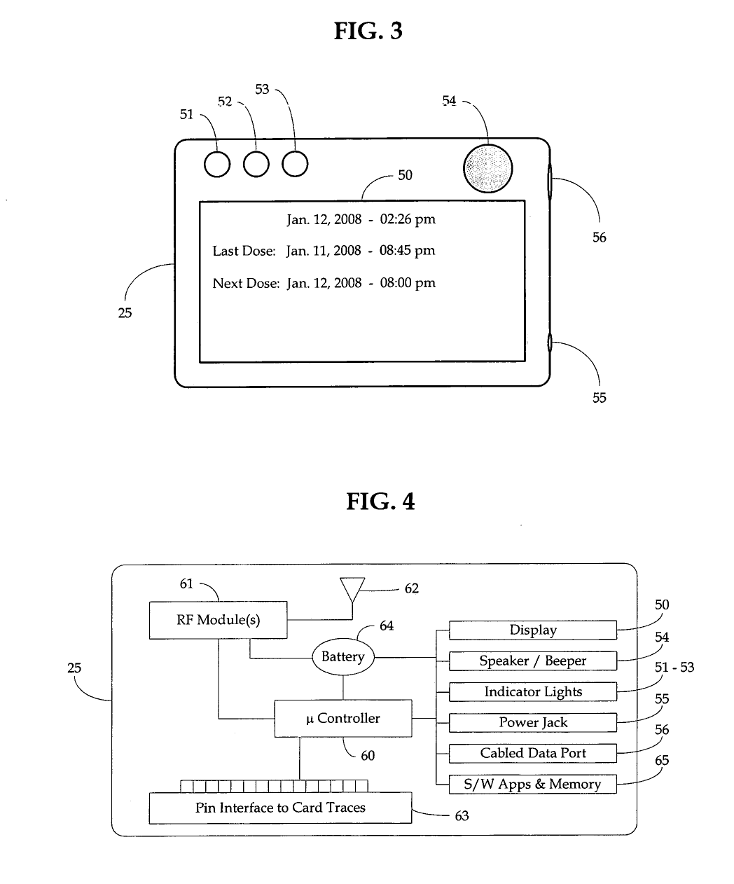

Referring to FIG. 3, an example electronics component 25 is illustrated from an exterior perspective. In addition to internal electrical components, the electronics component 25 can include one or more of a display 50, a set of LED lights 51, 52, 53, a speaker 54, a power jack 55, and a data port 56. Depending on the hardware and software capabilities of the electronics component 25, a display can be utilized to illustrate the current date/time, the date/time of the last recorded dose, and the date/time of the next scheduled dose. This information can be pre-programmed by the user via a device that can be coupled either wirelessly or via data port 56 to the software within the electronics component 25. In addition, one or more LED lights 51, 52, 53 can be color coded to indicate the current status of the next unit dose. For instance, a green LED 51 could indicate that a user is current with his medication. A yellow LED 52 could indicate that the user is within an hour of the next scheduled unit dose, and a red LED 53 could indicate that the user is past due on his next schedule dose. A speaker 54 could beep to give the user an audible status indicator. For instance, one beep could indicate that the next scheduled dose is within minutes while 3 beeps could indicate that the next scheduled dose is past due. The beeps can be repeated for a predetermined cyclical period.

The electronics component 25 can be powered by removable or re-chargeable batteries. If re-chargeable, a power jack 55 can allow an external source to re-charge the internal batteries when a power cable is inserted into the power jack 55. A data port can accept a data cable that would allow a wired transfer of data between the electronics component 25 and another device. This could be in addition to or in lieu of a wireless transmission mechanism. The data port can be a USB cable for instance but may also be adapted for other data formats as well.

Referring to FIG. 4, a block diagram of the internal components of an example electronics component 25 is illustrated. A microcontroller 60 coordinates the activities of the remaining components. A pin trace contact interface 63 provides the mechanism to complete circuit(s) individually between the rest of the electronics component 25 and a plurality of blister packs wherein each blister pack can be individually associated with an electrical trace such that rupturing a blister pack will also break the electrical trace associated with the blister pack. Such an event can create a detectable change in electrical potential throughout the entire circuit that indicates the dispensing of a unit dose. There is an assumption that the unit dose is then ingested by a user as prescribed.

The electronics component 25 can further comprise one or more of an RF module 61 and associated antenna 62, one or more batteries 64, a display 50, a speaker 54, LED indicator lights 51-53, a power jack 55, a data port 56, and software applications with associated memory 65.

The software applications and associated memory 65 can be programmed to respond variously to the detection of a rupture blister package. The event can be recorded and date/time stamped as data and packed into a message format suitable for wireless transmission over the RF module 61. The RF module 61 can include cellular protocols such as GSM or CDMA, or can be limited to more short range communication protocols such as Bluetooth, WiFI, or WiMax. Data can be received and/or sent between the electronics component 25 and one or more external devices utilizing the RF module 61 and a corresponding appropriate network. Or, the data can be sent out via the data port 56 which can be a USB cable or other suitable cable/data format pairing.

As described earlier, the microcontroller 60 can include a clock element that knows the current date/time and, in conjunction with the software application(s) 65 that has been programmed with a dosage schedule, provides visual and/or audible alerts and reminders to the user via the LED indicators 51-53 or the speaker 54.

FIG. 5 illustrates one embodiment of an electronics seating hub and an electronics component. In this example, the electronics component 25 includes one or more tabs 26 that are somewhat hook shaped. One or more detents 27 can also be included on either side of the electronics component 25 to help keep it in place when mechanically coupled with the electronics seating hub component 24. Also shown are a series of electrical trace contacts 28. The electronics seating hub component 24 is comprised of a housing 29 having a corresponding number of inverted detents 31 on the interior surface that are positioned to correspond with detents 27 when the electronics component 25 is mechanically coupled with the electronics seating hub component 24. The housing 29 further comprises electrical trace contacts 32 and one or more openings 30 that are adapted to receive the one or more tabs 26 such that the tabs 26, when properly manipulated will fit through the openings 30 and seat the electronics component 25 securely in the electronics seating hub component 24. To help achieve this, the housing 29 can include a cut out area 40 on the housing wall opposite the wall containing the openings 30. The cut out area 40 allows the user to more easily grip the electronics component when inserting and removing it into the electronics seating hub component 24.

In operation, the electronics component 25 is tilted so that the tabs 26 can fit through the openings 30 of the electronics seating hub component 24. The electronics component 25 can then be pivoted or rocked downward until the detents 27 and inverted detents 31 engage one another. This will also bring contacts 28 and contacts 32 into an operatively electrically coupled relationship and complete the circuitry contained on the slide card 20 and within the electronics component 25.

It should be noted that the orientation and placement of the contacts 28, 32, tabs 26, openings 30, cut out areas 40 and detents 27, 31 described above can be design choices and are not limited to only the configuration shown.

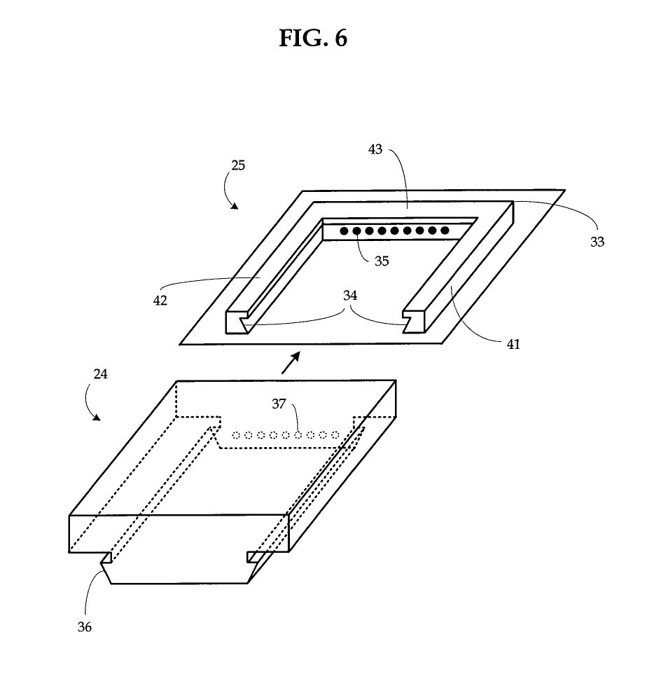

FIG. 6 illustrates another embodiment of an electronics seating hub and an electronics component. In this embodiment, the electronics seating hub component 24 is comprised of a rigid member 33 having opposing side members 41, 42 connected by an end member 43. The side members 41, 42 include a dovetail 34 slot extending substantially the length of the side members 41, 42. A plurality of electrical trace contacts 35 can be disposed on the interior surface of the end member 43.

The electrical component 25 includes a portion having a matching dovetail 36 pattern and electrical contacts 37 such that the electrical component can be slidably inserted into the electronics seating hub component 24 by aligning the matching dovetail portions. Upon full insertion of the electronics component 25 into the electronics seating hub component 24, contacts 35 and 37 will contact one another to create an electrically coupled relationship.

The coupling between the electronics seating hub component 24 and the electronics component 25 can be configured in other ways in addition to those described above. The embodiments described herein are not limited to merely the configurations described with reference to FIGS. 5 and 6.

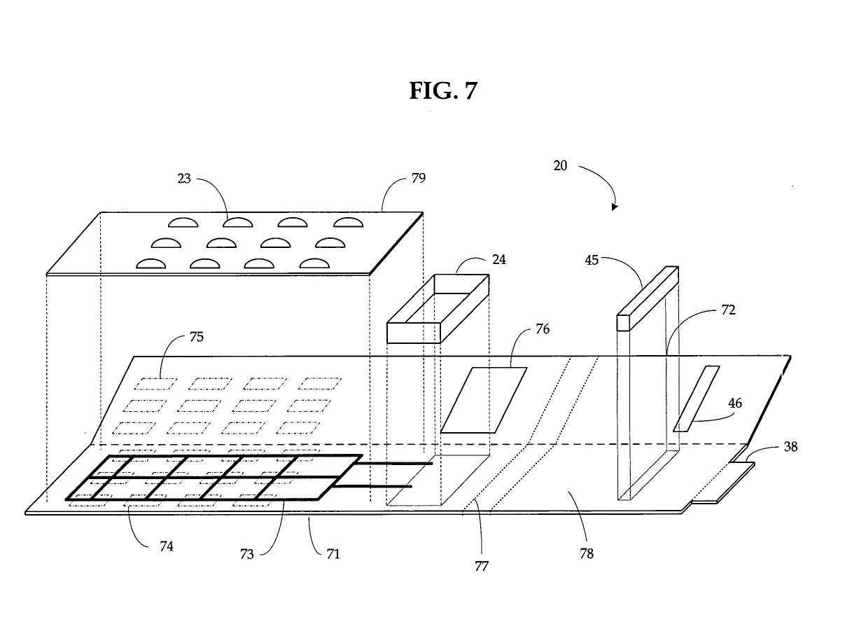

FIG. 7 is an exploded view of the various layers and components that comprise a slide card according to an embodiment of the disclosure. The slide card 20 starts as a reinforced blank that has been designed to receive one or more blister packs 79 comprised of individual unit doses 23. The slide card 20 generally comprises a bottom panel 71 and a top panel 72. The top panel 72 is designed to be folded over and sealed on top of the bottom panel 71. Alternatively, the top 72 and bottom 71 panels can be separate from one another wherein the top panel 72 is positioned over the bottom panel 71 rather than folded into place.

The bottom panel includes areas of weakness defined by perforations 74 such that sufficient force downward will cause the perforated area to tear leaving an opening in the bottom panel 71 capable of passing a unit dose. An electrical ink trace element 73 is applied to the bottom panel 71 such that each perforated area includes part of the electrical trace element 73. The electrical trace element 73 terminates in an area reserved for an electrical seating hub component 24. In addition, creases 77 allow for the slide card to be folded into another spatial dimension once the top panel 72 has been folded over the bottom panel 71. There is space 78 reserved on the panel for additional traces and blister packs as desired.

The top panel includes first cut out areas 75 for each individual unit dose 23 of blister pack 79. A second cut out area 76 is designed to allow the electrical seating hub component 24 to protrude from the slide card 20 once assembled. A third cut out area 46 is designed to allow protruding element 45 to protrude from the slide card 20 once assembled.

A locking mechanism 38 can also be included to provide enhanced child resistant functionality. The locking mechanism 38 is adapted to engage a first reciprocal catch 39 that is within the outer sleeve 10 shown in FIG. 1. To release the slide card locking mechanism 38, a user would depress the release mechanism 16 shown in FIG. 1.

Protruding element 45 also provides enhanced child resistant functionality in that it encounters electronics seating hub component 24 and electronics component 25 when a user tries to remove the top panel of the slide card 20. This action is prevented because the protruding element can not be pulled over the electronics seating hub component 24 and electronics component 25.

The illustrated electrical traces 73 can be applied directly on the slide card 20, in a manner well known by those skilled in the art. The electrical traces 73 can be printed on the slide card 20 using conventional printing or lithography methods such as but not limited to screen or off-set methods. The inks used in the printing method to form the circuitry are conductive inks, selected based on the performance needs of the individual circuits. Conductive inks typically include conductive metals such as but not limited to copper or silver. The ink used to form the illustrated electrical traces 73 can be a carbon-based conductive ink readily understood by those skilled in the art.

The electronics component 25 is designed to be reusable with respect to multiple unit dose slide card inserts. Thus, the actual electronics component is not shipped with the unit dose slide card insert originally. Rather, a user is responsible for inserting the electronics component 25 into the electronics seating hub component 24 when receiving the unit dose packaging system. However, since the electronics component 25 itself aids in enhancing the child resistant aspect of the packaging, the original packaging can have a dummy electronics component already seated in the electronics seating hub component 24. When a user receives the unit dose packaging system containing the dummy electronics component, he simply removes the dummy component and inserts the real electronics component 25.

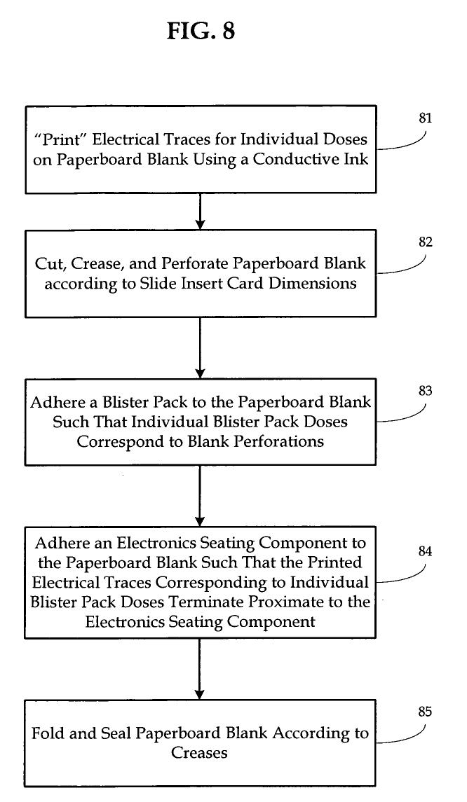

FIG. 8 is a data flow diagram that describes a process for assembling a slide card such as that illustrated in FIG. 7 according to an embodiment of the disclosure. The steps do not necessarily occur in chronological order. At 81, electrical traces are printed on the blank in the desired pattern so as to ensure each unit dose has a portion of the electrical trace associated therewith. At 82, the blank is then manipulated to contain all the creases, cut outs, and perforations required to accommodate the blister pack(s) and electronics seating hub component. At 83, the blister pack(s) are adhered to the bottom panel of the blank such that each unit dose is substantially over a perforated area. At 84, the electronics seating hub component is then adhered to the bottom panel such that the electrical trace terminations of the printed conductive ink are mated to corresponding electrical trace contacts in the electronics seating hub component. At 85, the blank is then folded over and sealed according to the creases thereby encasing the blister pack(s) and electronics seating hub component firmly and immovably between the top and bottom panels of the slide card.

As an alternative process for assembling a slide card, a blister pack and electronics seating hub component may be placed on the top panel, with the blister cavities and electronics seating hub component protruding through apertures in the top panel. These components may be adhered to the top card. The bottom panel would be folded over and the entire structure sealed at one time.

It is believed that the present disclosure includes many other embodiments that may not be herein described in detail, but would nonetheless be appreciated by those skilled in the art from the disclosures made. Accordingly, this disclosure should not be read as being limited only to the foregoing examples or only to the designated preferred embodiments.

1. A unit dose package insert comprising:
a blank comprised of a bottom panel and a top panel,
the bottom panel including one or more areas of weakness, an electrical trace element having at least first and second ends positioned away from the one or more areas of weakness, wherein the electrical trace element intersects the one or more areas of weakness such that when an area of weakness is compromised the electrical trace element is broken for that area of weakness, and
the top panel including one or more unit dose cut out areas and an electronics seating hub component cut out area;
a blister pack comprised of one or more sealed unit doses positionable atop the bottom panel; and
an electronics seating hub component adapted to mechanically receive an electronics component, wherein the electronics seating hub component is positioned proximate to the at least first and second ends of the electrical trace element,
wherein the top panel substantially covers and is adhered to the bottom panel so as to secure the blister pack and electronics seating hub component between the top and bottom panel such that the sealed unit doses protrude through the unit dose cut out areas and the electronics seating hub component protrudes through the electronics seating hub component cut out area.

2. The unit dose package insert of claim 1 wherein the blank includes a crease that defines a boundary between the top panel and the bottom panel such that folding the blank along the crease positions the top panel substantially covering the bottom panel aligning the cut out areas of the top panel with the areas of weakness of the bottom panel.

3. The unit dose package insert of claim 1 wherein the blank further comprises a pair of creases in which the space between the pair of creases defines an end panel when the unit dose package insert is folded back over itself along the creases creating an upper portion and a lower portion separated by the end panel.

4. The unit dose package insert of claim 3 further comprising a protruding element attached to the upper portion and positioned to be proximate the electronics seating hub component when the unit dose package insert is folded back over itself such that the protruding element is obstructed by the electronics seating hub component upon trying to slide the upper portion with respect to the lower portion.

5. The unit dose package insert of claim 4 wherein the blank comprises paperboard.

6. The unit dose package insert of claim 1 wherein the electronics seating hub component comprises:
a housing comprised of a first and second pair of opposing walls each having a base associated therewith, wherein
one wall of the first pair of opposing walls includes at least one opening at the base of the wall that is adapted to receive a tab that is attached to an electronics component and the opposite wall of the first pair of opposing walls includes a cut out area to facilitate insertion and removal of the electronics component within the electronics seating hub component; and
one wall of the second pair of opposing walls includes a detent adapted to receive a corresponding inverted detent that is attached to an electronics component such that the electronics component remains seated in place upon lining up the detent and inverted detent.

7. The unit dose package insert of claim 1 wherein the electronics seating hub component comprises:
a pair of opposed rigid side members including a dovetail slot extending substantially the length of each side member;
a rigid cross member including one or more electrical contacts that are electrically coupled with the electrical trace element ends,
wherein an electronics component having a corresponding dovetail slot can be slidably seated with the electronics seating hub component.

8. A reusable electronics component adapted to communicate with a disposable unit dose package to collect and disseminate data pertaining to the expression of unit doses comprising:
a seating mechanism adapted to fit into an electronics seating hub component, wherein the seating mechanism enables the electronics component to be removed from the electronics seating hub component without causing damage to the electronics component;
a microcontroller;
an electrical trace contact interface coupled with the microcontroller, wherein the electrical trace contact interface is positioned relative to the seating mechanism enabling the electronics component to receive signals from electrical traces present on the disposable unit dose package,
wherein the microcontroller is programmed to detect, based on the signals, when a unit dose has been expelled from the disposable unit package.

9. The reusable electronics component of claim 8 further comprising a display for displaying data.

10. The reusable electronics component of claim 8 further comprising an indicator light for providing a visual status indication.

11. The reusable electronics component of claim 8 further comprising a speaker for providing an audible status indication.

12. The reusable electronics component of claim 8 further comprising a power jack for recharging an internal power source of the electronics component.

13. The reusable electronics component of claim 8 further comprising a data port for providing a wired data output mechanism.

14. A method of assembling a unit dose package insert comprising:
forming a blank comprised of a top panel and a bottom panel, wherein the top panel and a bottom panel include one or more creases, cut outs, and perforations required to accommodate a blister pack and an electronics seating hub component;
applying electrical traces to the blank in a desired pattern so as to ensure each unit dose has a portion of the electrical trace associated therewith;
adhering the blister pack to the bottom panel of the blank such that each unit dose is substantially over a perforated area;
adhering an electronics seating hub component to the bottom panel such that electrical trace terminations are coupled with corresponding electrical trace contacts in the electronics seating hub component; and
sealing the top panel to the bottom panel thereby encasing the blister pack and the electronics seating hub component firmly and immovably between the top and bottom panels of the unit dose package insert.

15. The method of claim 14 further comprising adhering a protruding element attached to the bottom panel.

16. The method of claim 14 wherein the electrical traces are comprised of conductive ink that is printed onto the blank.

17. A unit dose package system comprising:
a slide card insert comprised of a blank that includes a bottom panel and a top panel,
the bottom panel including one or more areas of weakness, an electrical trace element having at least first and second ends positioned away from the one or more areas of weakness, wherein the electrical trace element intersects the one or more areas of weakness such that when an area of weakness is compromised the electrical trace element is broken for that area of weakness, and
the top panel including one or more unit dose cut out areas and an electronics seating hub component cut out area;
a blister pack comprised of one or more sealed unit doses positionable atop the bottom panel,
wherein the top panel substantially covers and is adhered to the bottom panel thereby securing the one or more blister packs and electronics seating hub component securely between the top and bottom panel such that the sealed unit doses protrude through the unit dose cut out areas and the electronics seating hub component protrudes through the electronics seating hub component cut out area;
an electronics seating hub component adapted to mechanically receive a removable, reusable electronics component wherein the electronics seating hub component is positioned proximate to the termination of the electrical trace element ends; and
a reusable electronics component mechanically and electrically coupled with the electronics seating hub component to create a complete electrical circuit between each unit dose and the reusable electronics component;
a protruding element positioned to be proximate the electronics seating hub component when the slide card insert is folded back over itself creating an upper and lower portion, the protruding element is obstructed by the electronics seating hub component upon trying to slide the upper portion with respect to the lower portion; and
a child resistant outer sleeve adapted to receive the slide card insert such that the slide card insert is lockably and slidably engaged within the child resistant outer sleeve.

18. An insert for a package for holding medication, comprising:
a slide card including at least one area of weakness formed therein;
an electrical trace element including at least first and second ends positioned away from the area of weakness, wherein the electrical trace element intersects the area of weakness such that when the area of weakness is compromised, the electrical trace element is broken for the area of weakness; and
an electronics seating hub component adapted to mechanically receive an electronics component, wherein the electronics seating hub is positioned proximate to the at least first and second ends of the electrical trace element.

19. The insert of claim 18 further comprising a protruding element positioned to be proximate the electronics seating hub component when the slide card is folded back over itself creating an upper and lower portion, wherein the protruding element is obstructed by the electronics seating hub component upon trying to slide the upper portion with respect to the lower portion.

20. The insert of claim 18 wherein the electronics seating hub component is further adapted to release the electronic component without causing damage thereto.

21. The insert of claim 18 further comprising an electronics component, wherein the electronics component is removably attached to the electronics hub seating component, and wherein the electronics component is in electrical contact with the at least first and second ends of the electrical trace element.

22. The insert of claim 18 further comprising a blister package holding medication.

23. The insert of claim 18 further comprising a blister package holding a unit dose of medication, wherein the blister package is generally aligned with the slide card such that the unit dose of medication is aligned with the at least one area of weakness.

24. The insert of claim 21 wherein the electronics component is programmed to detect when the unit dose of medication is expressed through the area of weakness.

25. The insert of claim 21 wherein the electronics component is further programmed to communicate when the unit dose of medication is expressed through the area of weakness.

26. The insert of claim 18 wherein the slide card comprises paperboard.

27. A package for holding medication, comprising:
a slide card including at least one area of weakness formed therein;
an electrical trace element including at least first and second ends positioned away from the area of weakness, wherein the electrical trace element intersects the area of weakness such that when the area of weakness is compromised, the electrical trace element is broken for the area of weakness;
an electronics seating hub component adapted to mechanically receive an electronics component, wherein the electronics seating hub is positioned proximate to the at least first and second ends of the electrical trace element; and
a sleeve which houses the slide card.

28. The package of claim 27 wherein the slide card further comprises a locking mechanism, wherein the sleeve further comprises a reciprocal locking mechanism, and wherein the locking mechanism and the reciprocal locking mechanism cooperate to lock the card within the sleeve.

29. The package of claim 28 wherein the sleeve further comprises a release located proximate the reciprocal locking mechanism, wherein the release, when activated, enables the slide card to be moved substantially outside of the sleeve.

30. The package of claim 27 wherein the package is child resistant compliant.

31. The package of claim 27 further comprising an electronics component, wherein the electronics component is removably attached to the electronics hub seating component, and wherein the electronics component is in electrical contact with the at least first and second ends of the electrical trace element.

32. The package of claim 27 further comprising a protruding element positioned to be proximate the electronics seating hub component when the slide card is folded back over itself creating an upper and lower portion, wherein the protruding element is obstructed by the electronics seating hub component upon trying to slide the upper portion with respect to the lower portion.

33. The package of claim 27, further comprising a dummy electronics component attached to the electronics seating hub component.

34. The package of claim 31, wherein the electronics seating hub component is further adapted to release the electronic component without causing damage thereto.
